(19) United States
(12) Patent Application Publication
(10) Pub. No.: US 2005/0063160 A1
(43) Pub. Date: Mar. 24, 2005

(54) Heat-dissipating plate module

(76) Inventor: Richard Ma, Taipei (TW)

Correspondence Address: BIRCH STEWART KOLASCH & BIRCH, PO BOX 747, FALLS CHURCH, VA, 22040-0747, US

(21) Appl. No.: 10/667,371

(22) Filed: Sep. 23, 2003

(51) Int. Cl. H05K 7/20

(52) U.S. Cl. 361/704

(57) ABSTRACT

A heat-dissipating plate module installed on a heat-generating component of an electronic device for dissipating heat generated there by is disclosed. The heat-dissipating plate module is comprised of a heat-conductive base and several heat-dissipating plates. The heat-conductive base is in direct contact with the heat-generating component for heat transfer. Each heat-dissipating plate has several pillar-like protruding parts for increasing the dissipation area. The protruding parts of adjacent heat-dissipating plates are distributed in a non-overlapping way so that the airflow paths in between are continuously curved. This can elongate the heat transfer time to enhance the heat dissipation efficiency.

### BACKGROUND OF THE INVENTION

1. Field of Invention

The invention relates to a heat dissipation structure and, in particular, to a heat-dissipating plate module for heat-generating components in electronic devices that is in general accompanied by a side-blowing fan.

2. Related Art

Heat dissipation is a major subject in electronic device designs. An electronic device is comprised of a lot of electronic elements. Taking the computer as an example, there are many electronic elements on the motherboard that can generate a tremendous amount of heat during operations. Such elements include the central processing unit (CPU), the south/north bridge chips, the graphics chip, and the dual in-line memory modules (DIMM's). The operation speeds of these electronic elements become much faster than before. For example, the work frequency of the CPU is now over 1 GHz, with a heat-dissipating power of 50 W. If the heat cannot be immediately removed, these electronic elements may be overheated to affect their stability and reliability and to shorten their lifetime. Therefore, heat dissipation is a serious problem when the electronic device operation frequencies become higher.

Currently, the electronic device heat dissipation is achieved by heat conduction, convection or radiation to release the generated heat to the environment. A primary means is to use the combination of a heat-dissipating plate module and a fan. The heat-dissipating plate module is made of metal. It has a heat-conductive base whose bottom is directly installed on the electronic device that generates heat. The heat-conductive base is formed with several heat-dissipating plates to help dissipating heat. The heat produced by the heat-generating electronic device is transferred via the heat-conductive base to the heat-dissipating plates. The fan generates airflow through the plates to have heat exchange. The heated air is then expelled to the ambient space, bringing away the heat on the heat-dissipating plate module and lowering the temperature of the electronic device.

Generally speaking, the heat-dissipation efficiency of the plate module is usually determined by its material and structure. The early heat-dissipating plate modules are often made of aluminum because of its small thermal resistance, light weight and low cost. However, as the electronic device work frequency continuously increases, the heat-dissipation efficiency has to be increased too. Therefore, people start to use copper as the material for heat-dissipating modules. The thermal conduction coefficient of copper is about 1.8 times that of aluminum, while the density of copper is about 3 times that of aluminum. In other words, for heat-dissipating plate modules of the same volume and area, the one made of copper is 3 times heavier than that made of aluminum. Therefore, although the heat-dissipating plate module made of copper has a better thermal conduction coefficient than that made of aluminum; the former is much heavier than the latter. One thus has to take both the weight and the thermal conduction coefficient factors into account when making the plates.

Existing heat-dissipating plate modules on the market are all made of materials with similar compositions. The heat-dissipation efficiencies are also very close. Therefore, how to increase heat dissipation by having a better structure has become the main research goal of the manufacturers. For example, the heat-dissipating plates are usually installed vertically on the base of a heat-dissipating plate module. One of the features of a vertical heat-dissipating plate module is that the flat plates provide straight airflow channels. However, the drawbacks of this structure are that the heat-conductive area is too small, that the heat transfer time is too short, and that the parallel airflow cannot provide ideal heat convection once leaving the separation of the plates. Although the patent provides a layered structure, the structure and arrangement of the vertical structure still have room for improvement.

### SUMMARY OF THE INVENTION

The invention is aimed at solving the problems in the prior art of vertical heat-dissipating plate structure that the dissipation area is small, that the heat transfer time is short, and that the straight airflow path cannot provide ideal heat convection effects.

In view of the foregoing, the disclosed heat-dissipating plate module includes: a heat-conductive base and several heat-dissipating plates. The heat-conductive base is installed on a heat-generating component of an electronic device. The heat-dissipating plates are installed vertically at intervals on the heat-conductive base in a parallel way. Each heat-dissipating plate has a flat body and several pillar-like protruding parts distributed thereon. The protruding parts of any two adjacent heat-dissipating plates do not overlap, forming an airflow space with continuously curved airflow paths.

The invention uses the heat-dissipating plate structure that has pillar-like protruding parts to increase the heat dissipation area. With the non-overlapping configuration of the protruding parts between adjacent heat-dissipating plates, the continuously curved airflow paths thus formed can further increase the heat transfer time and efficiency.

### BRIEF DESCRIPTION OF THE DRAWINGS

The invention will become more fully understood from the detailed description given hereinbelow illustration only, and thus are not limitative of the present invention, and wherein:

FIG. 1 is a three-dimensional appearance of the first embodiment of the invention;

FIG. 2 is a schematic top view of FIG. 1;

FIG. 3 is a schematic local top view of the second embodiment of the invention;

FIG. 4 is a schematic local top view of the third embodiment of the invention;

FIG. 5 is a schematic local top view of the fourth embodiment of the invention; and

FIG. 6 is a schematic local top view of the fifth embodiment of the invention.

### DETAILED DESCRIPTION OF THE INVENTION

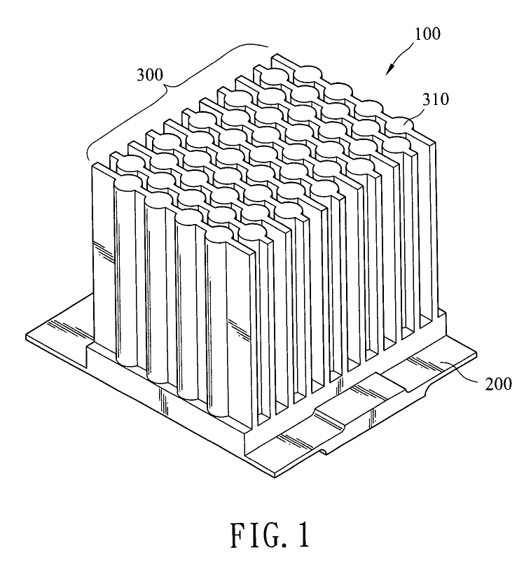

With simultaneous reference to FIGS. 1 and 2, the heat-dissipating plate module 100 according to a preferred embodiment of the invention can be used on heat-generating devices such as the CPU, the south/north bridge chips, the graphics chip, and the DIMM's, avoiding the devices from damages due to overheating.

The heat-dissipating plate module 100 is made of metals with high thermal conduction coefficients (e.g. aluminum and copper). It consists of a heat-conductive base 200 and several first heat-dissipating plates 300.

The heat-conductive base 200 is a piece of block that fits that shape of the heat-generating device. Its bottom is attached to the heat-generating device (not shown) for direct contact. Generally speaking, a heat-dissipating gel is applied between the heat-conductive base 200 and the heat-generating device, increasing the thermal conductance of the system.

The heat-dissipating plates 300 are installed vertically at intervals on the top surface of the heat-conductive base 200 (see FIG. 1). Each of the heat-dissipating plates 300 has a flat body with several round pillar-like protruding parts 310 distributed thereon. The heat-dissipating plates 300 can be fixed on the heat-conductive base 200 by gluing or welding. They can also be formed directly by cutting or squeezing.

All the heat-dissipating plates 300 are equal in length, parallel to one another, and trimmed on the outer side. The protruding parts 310 of any two adjacent heat-dissipating plates 300 do not overlap, forming an airflow space with continuously curved airflow paths in between.

After installing the disclosed heat-dissipating plate module 100 on a heat-generating device, a fan is usually provided on one side (not shown) to produce airflow. The airflow paths are shown in FIG. 2. Since all the heat-dissipating plates 300 have the round pillar-like protruding parts, there is a larger heat dissipation area than simply flat ones and the curved airflow paths elongate the heat transfer time, rendering better heat dissipation.

In the first embodiment of the invention, if one wants the airflow paths to be specific without any place being too narrow the intervals among the protruding parts 310 on each heat-dissipating plate 300 have to be the same. Therefore, the protruding parts 310 are distributed in a regular pattern for unifying all airflow paths.

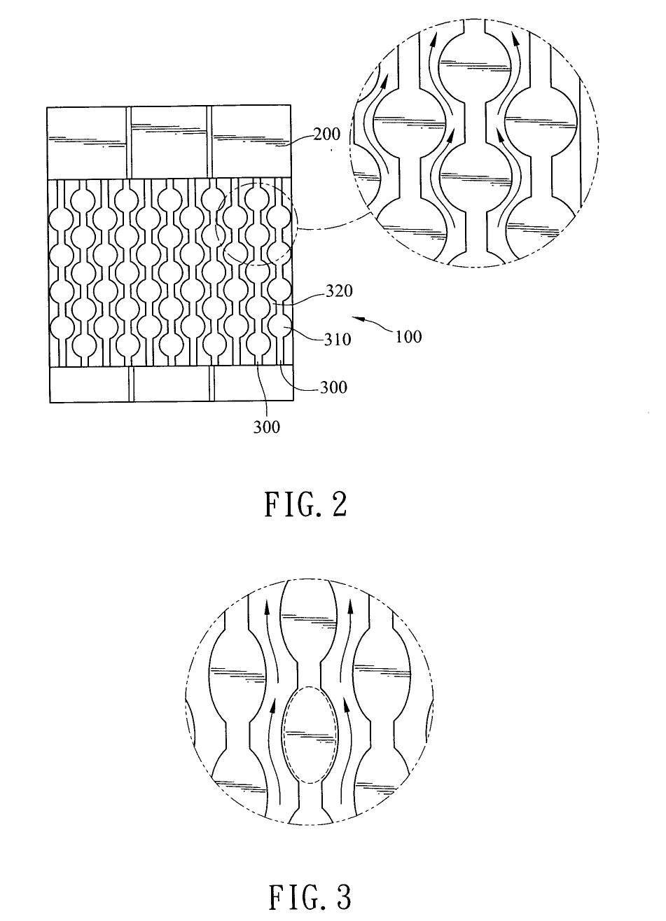

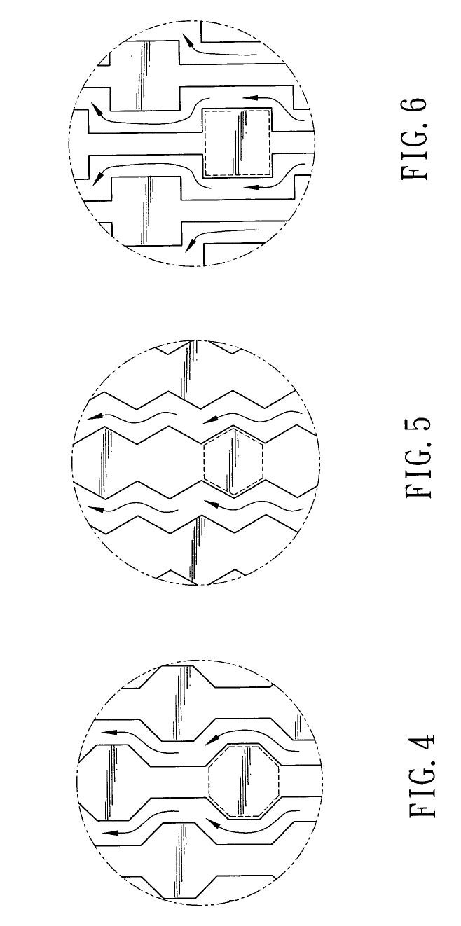

FIGS. 3, 4, 5 and 6 are schematic local top views of the second, third, fourth, and fifth embodiments of the invention. One may not need round pillar-like protruding parts to achieve continuously curved airflow paths. For instance, elliptical pillars (FIG. 3), octagonal pillars (FIG. 4), hexagonal pillars (FIG. 5), and square pillars (FIG. 6) can all achieve similar effects.

Certain variations would be apparent to those skilled in the art, which variations are considered within the spirit and scope of the claimed invention.

1. A heat-dissipating plate module comprising:
a heat-conductive base, which is installed on a heat-generating component of an electronic device; and
a plurality of heat-dissipating plates installed vertically at intervals on the heat-conductive base, each of which has a flat body with a plurality of pillar-like protruding parts and the protruding parts of any two adjacent heat-dissipating plates do not overlap, forming an airflow space with continuously curved airflow paths in between.

2. The heat-dissipating plate module of claim 1, wherein the protruding parts are elliptical pillars, round pillars, polygonal pillars, octagonal pillars, hexagonal pillars or square pillars.

3. The heat-dissipating plate module of claim 1, wherein the distance between any two adjacent protruding parts is the same.

4. The heat-dissipating plate module of claim 1, wherein all of the heat-dissipating plates are equal in length.

5. The heat-dissipating plate module of claim 1, wherein the centers of the heat-dissipating plates are on a same line.

6. The heat-dissipating plate module of claim 1, wherein the outer sides of the heat-dissipating plates are trimmed.

7. The heat-dissipating plate module of claim 1, wherein the heat-dissipating plates are fixed on the heat-conductive base by a method selected from gluing and welding.
